(19) United States
(12) Patent Application Publication
(10) Pub. No.: US 2019/0389991 A1
(43) Pub. Date: Dec. 26, 2019

(54) POLYMER AND POSITIVE RESIST COMPOSITION

(71) Applicant: ZEON CORPORATION, Chiyoda-ku Tokyo (JP)

(72) Inventor: Takashi TSUTSUMI, Chiyoda-ku, Tokyo (JP)

(73) Assignee: ZEON CORPORATION, Chiyoda-ku Tokyo (JP)

(21) Appl. No.: 16/489,145

(22) PCT Filed: Feb. 21, 2018
(86) PCT No.: PCT/JP2018/006272

§ 371 Date: Aug. 27, 2019

(30) Foreign Application Priority Data
Mar. 17, 2017 (JP) 2017-053308

(51) Int. Cl. C08F 220/22; C08F 212/08; G03F 7/039; C08F 220/28

(52) U.S. Cl. CPC C08F 220/22; C08F 212/08; C08F 2220/283; C08F 220/28; G03F 7/039

(57) ABSTRACT

Provided is a polymer that can form a resist pattern having excellent dry etching resistance when used as a main chain scission-type positive resist. The polymer includes a monomer unit (A) represented by formula (I), shown below, and a monomer unit (B) represented by formula (II), shown below. In formula (I), B is a bridged saturated hydrocarbon cyclic group that is optionally substituted and n is 0 or 1. In formula (II), R¹ is an alkyl group and p is an integer of not less than 0 and not more than 5. In a case in which more than one R¹ is present, each R¹ may be the same or different.

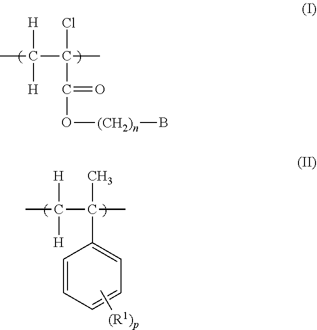

### TECHNICAL FIELD

The present disclosure relates to a polymer and a positive resist composition, and in particular relates to a polymer that is suitable for use as a positive resist and a positive resist composition that contains this polymer.

### BACKGROUND

Polymers that undergo main chain scission to lower molecular weight upon irradiation with ionizing radiation such as an electron beam or short-wavelength light such as ultraviolet light (inclusive of extreme ultraviolet (EUV)) are conventionally used as main chain scission-type positive resists in fields such as semiconductor production. (Hereinafter, the term “ionizing radiation or the like” is used to refer collectively to ionizing radiation and short-wavelength light.)

Patent Literature (PTL) 1, for example, reports that a resist pattern having excellent dry etching resistance can be formed using a positive resist composed of an α-methylstyrene-methyl α-chloroacrylate copolymer that includes an α-methylstyrene unit and a methyl α-chloroacrylate unit in a specific ratio.

### CITATION LIST

### Patent Literature

PTL 1: JP H8-3636 B

### SUMMARY

### Technical Problem

However, with regards to a positive resist composed of the α-methylstyrene-methyl α-chloroacrylate copolymer described in PTL 1, there is demand for further increasing dry etching resistance of a resist pattern.

Accordingly, an objective of the present disclosure is to provide a polymer that can form a resist pattern having excellent dry etching resistance when used as a main chain scission-type positive resist and a positive resist composition containing this polymer.

### Solution to Problem

The inventor conducted diligent studies with the aim of achieving the objective described above. As a result, the inventor discovered that a resist pattern having excellent dry etching resistance can be formed by using a specific polymer, formed using specific monomers, as a main chain scission-type positive resist. In this manner, the inventor completed the present disclosure.

Specifically, the present disclosure aims to advantageously solve the problem set forth above by disclosing a polymer comprising:

a monomer unit (A) represented by formula (I), shown below,

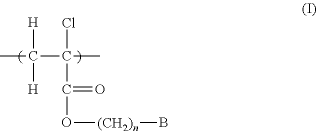

where, in formula (I), B is a bridged saturated hydrocarbon cyclic group that is optionally substituted and n is 0 or 1; and

a monomer unit (B) represented by formula (II), shown below,

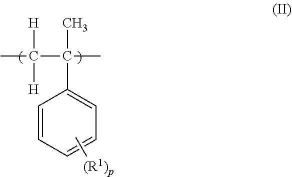

where, in formula (II), R¹ is an alkyl group and p is an integer of not less than 0 and not more than 5, and in a case in which more than one R¹ is present, each R¹ may be the same or different.

By using a polymer including the monomer unit (A) and the monomer unit (B) set forth above, an obtained resist pattern can be caused to display excellent dry etching resistance.

In the presently disclosed polymer, it is preferable that n is 0. A polymer in which n is 0 and in which the bridged saturated hydrocarbon cyclic group is directly bonded to a non-carbonyl oxygen atom of an ester bond readily undergoes main chain scission upon irradiation with ionizing radiation or the like (i.e., has high sensitivity to ionizing radiation or the like). Moreover, a resist pattern can be efficiently formed using this polymer. Furthermore, a polymer in which n is 0 and in which the bridged saturated hydrocarbon cyclic group is directly bonded to a non-carbonyl oxygen atom of an ester bond has a high glass-transition temperature (Tg). The heat resistance of a resist pattern can be improved by using a polymer that has a high glass-transition temperature.

In the presently disclosed polymer, B is preferably an optionally substituted adamantyl group. A polymer in which B is an optionally substituted adamantyl group has high sensitivity to ionizing radiation or the like. Moreover, a resist pattern can be efficiently formed using this polymer.

The present disclosure also aims to advantageously solve the problem set forth above by disclosing a positive resist composition comprising any one of the polymers described above and a solvent. By using a positive resist composition that contains the polymer described above, a resist pattern having excellent dry etching resistance can be formed.

### Advantageous Effect

According to the present disclosure, it is possible to provide a polymer that can form a resist pattern having excellent dry etching resistance when used as a main chain scission-type positive resist.

Moreover, according to the present disclosure, it is possible to provide a positive resist composition that can form a resist pattern having excellent dry etching resistance.

### DETAILED DESCRIPTION

The following provides a detailed description of embodiments of the present disclosure.

Note that the term “optionally substituted” as used in the present disclosure means “unsubstituted or having one or more substituents”.

The presently disclosed polymer can be favorably used as a main chain scission-type positive resist that undergoes main chain scission to lower molecular weight upon irradiation with ionizing radiation, such as an electron beam, or short-wavelength light, such as ultraviolet light. Moreover, the presently disclosed positive resist composition contains the presently disclosed polymer as a positive resist and can be used, for example, in formation of a resist pattern in a production process of a semiconductor, a photomask, a mold, or the like.

(Polymer)

A feature of the presently disclosed polymer is that the polymer includes:

a monomer unit (A) represented by formula (I), shown below,

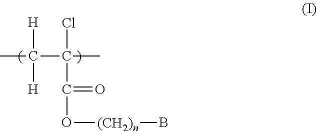

where, in formula (I), B is a bridged saturated hydrocarbon cyclic group that is optionally substituted and n is 0 or 1; and

a monomer unit (B) represented by formula (II), shown below,

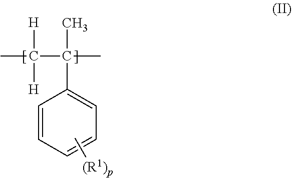

where, in formula (II), R¹ is an alkyl group and p is an integer of not less than 0 and not more than 5, and in a case in which more than one R¹ is present, each R¹ may be the same or different.

Although the presently disclosed polymer may further include any monomer units other than the monomer unit (A) and the monomer unit (B), the total proportion constituted by the monomer unit (A) and the monomer unit (B) among all monomer units included in the polymer is preferably 90 mol % or more, and more preferably 100 mol % (i.e., the polymer more preferably only includes the monomer unit (A) and the monomer unit (B)).

As a result of the presently disclosed polymer including these specific monomer units (A) and (B), the presently disclosed polymer undergoes main chain scission to lower molecular weight upon irradiation with ionizing radiation or the like (for example, an electron beam, KrF laser, ArF laser, or EUV laser). The presently disclosed polymer includes a bridged saturated hydrocarbon cyclic group in the monomer unit (A). A polymer including such a bridged saturated hydrocarbon cyclic group is resistant to decomposition caused by ions, fast neutral particles, radicals, or the like used in dry etching. This is presumed to be due to the contribution of the bulky and rigid structure of the bridged saturated hydrocarbon ring. Therefore, a resist pattern having excellent dry etching resistance can be favorably formed by using the presently disclosed polymer as a main chain scission-type positive resist.

<Monomer unit (A)>

The monomer unit (A) is a structural unit that is derived from a monomer (a) represented by formula (III), shown below.

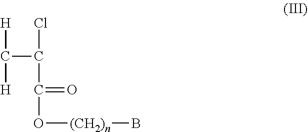

### [In Formula (III), B and n are the Same as in Formula (I).]

Although no specific limitations are placed on the proportion constituted by the monomer unit (A) among all monomer units included in the polymer, this proportion may, for example, be not less than 30 mol % and not more than 70 mol %.

The “bridged saturated hydrocarbon cyclic group” that can constitute B in formulae (I) and (III) is a group having a ring structure including at least one bridging group that links two or more non-adjacent atoms in a saturated hydrocarbon ring having the highest carbon number among rings in the group (i.e., the largest saturated hydrocarbon ring).

The largest saturated hydrocarbon ring may, for example, be cyclohexane or cyclooctane.

The bridging group linking two or more non-adjacent atoms in the largest saturated hydrocarbon ring may be any divalent group without any specific limitations, but is preferably an alkylene group, and more preferably a methylene group.

Specific examples of the bridged saturated hydrocarbon cyclic group include an adamantyl group and a norbornyl group. The bridged saturated hydrocarbon cyclic group is preferably an adamantyl group from a viewpoint of improving sensitivity of the polymer to ionizing radiation or the like.

The bridged saturated hydrocarbon cyclic group that can constitute B in formulae (I) and (III) is optionally substituted. Examples of possible substituents of the bridged saturated hydrocarbon cyclic group include, but are not specifically limited to, alkyl groups such as a methyl group and an ethyl group, and a hydroxy group. In a case in which the bridged saturated hydrocarbon cyclic group has more than one substituent, these substituents may be the same or different. Moreover, in a case in which the bridged saturated hydrocarbon cyclic group has more than one substituent, two substituents may be bonded such as to form a heterocycle such as a lactone ring (for example, a γ-butyrolactone ring) or a lactam ring.

From a viewpoint of improving sensitivity of the polymer to ionizing radiation or the like while also increasing the glass-transition temperature of the polymer and improving heat resistance of a resist pattern, it is preferable that n in formulae (I) and (III) is 0.

Examples of the monomer (a) represented by the previously described formula (III) that can form the monomer unit (A) represented by the previously described formula (I) include, but are not specifically limited to, α-chloroacrylic acid esters having a bridged saturated hydrocarbon cyclic group such as (a-1) to (a-14), shown below.

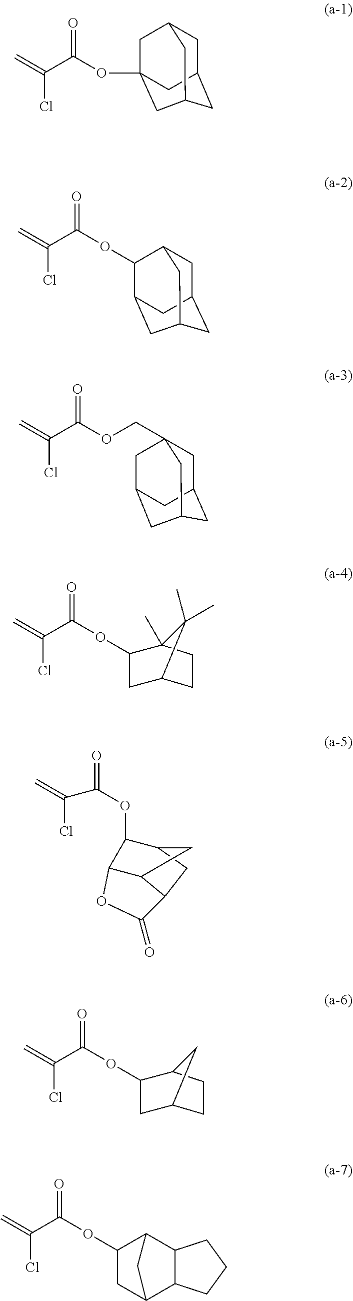

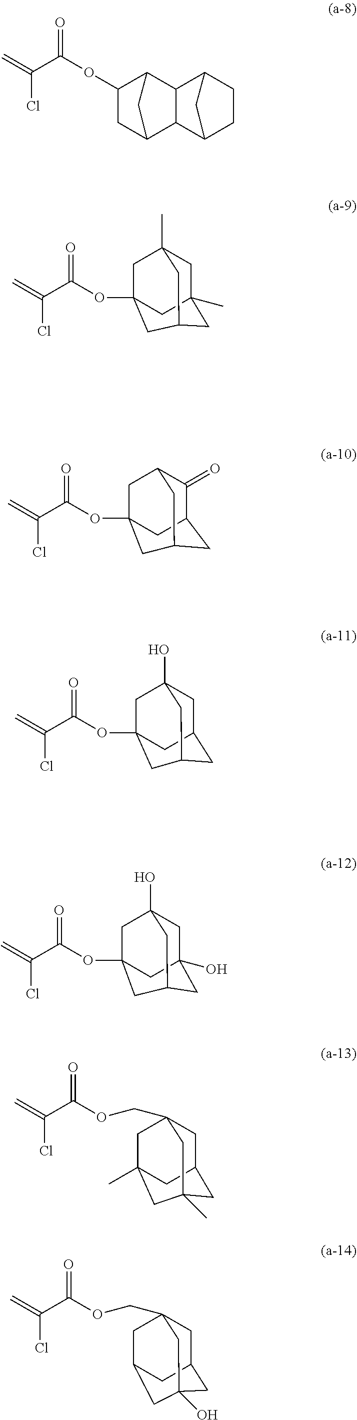

Of these examples, (a-1) to (a-5) are more preferable, and (a-1) and (a-2) are even more preferable from a viewpoint of improving dry etching resistance of a resist pattern.

<Monomer unit (B)>

The monomer unit (B) is a structural unit that is derived from a monomer (b) represented by formula (IV), shown below.

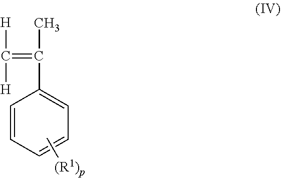

### [In Formula (IV), R¹ and p are the Same as in Formula (II).]

Although no specific limitations are placed on the proportion constituted by the monomer unit (B) among all monomer units included in the polymer, this proportion may, for example, be not less than 30 mol % and not more than 70 mol %.

Examples of alkyl groups that can constitute R¹ in formulae (II) and (IV) include, but are not specifically limited to, unsubstituted alkyl groups having a carbon number of 1 to 5. Of such alkyl groups, a methyl group or an ethyl group is preferable as an alkyl group that can constitute R′.

From viewpoints of ease of production of the polymer and improving sensitivity of the polymer to ionizing radiation or the like, it is preferable that p in formulae (II) and (IV) is 0. In other words, the monomer unit (B) is preferably a structural unit that is derived from α-methylstyrene (i.e., an α-methylstyrene unit).

(Production Method of Polymer)

The polymer including the monomer unit (A) and the monomer unit (B) set forth above can be produced, for example, by carrying out polymerization of a monomer composition that contains the monomer (a) and the monomer (b), and then optionally purifying the obtained polymerized product.

<Polymerization of Monomer Composition>

The monomer composition used in production of the presently disclosed polymer may be a mixture containing a monomer component that includes the monomer (a) and the monomer (b), an optional solvent, a polymerization initiator, and optionally added additives. Polymerization of the monomer composition may be carried out by a known method. In particular, the use of cyclopentanone or the like as the solvent is preferable, and the use of a radical polymerization initiator such as azobisisobutyronitrile as the polymerization initiator is preferable.

A polymerized product obtained through polymerization of the monomer composition may, without any specific limitations, be collected by adding a good solvent such as tetrahydrofuran to a solution containing the polymerized product and subsequently dripping the solution to which the good solvent has been added into a poor solvent such as methanol to coagulate the polymerized product.

<Purification of Polymerized Product>

The method of purification in a case in which the obtained polymerized product is purified may be, but is not specifically limited to, a known purification method such as re-precipitation or column chromatography. Of these purification methods, purification by re-precipitation is preferable.

Note that purification of the polymerized product may be performed repeatedly.

Purification of the polymerized product by re-precipitation is, for example, preferably carried out by dissolving the resultant polymerized product in a good solvent such as tetrahydrofuran, and subsequently dripping the resultant solution into a mixed solvent of a good solvent, such as tetrahydrofuran, and a poor solvent, such as methanol, to precipitate a portion of the polymerized product.

Also note that in a situation in which the polymerized product is purified by re-precipitation, polymerized product that precipitates in the mixed solvent of the good solvent and the poor solvent may be used as the presently disclosed polymer, or polymerized product that does not precipitate in the mixed solvent (i.e., polymerized product dissolved in the mixed solvent) may be used as the presently disclosed polymer. Polymerized product that does not precipitate in the mixed solvent can be collected from the mixed solvent by a known technique such as concentration to dryness.

(Positive Resist Composition)

The presently disclosed positive resist composition contains the polymer set forth above and a solvent, and may optionally further contain known additives that can be included in resist solutions. As a result of the presently disclosed positive resist composition containing the polymer set forth above as a positive resist, the presently disclosed positive resist composition can be used to form a resist pattern having excellent dry etching resi stance.

<Solvent>

The solvent may be any solvent in which the polymer set forth above is soluble without any specific limitations. For example, known solvents such as those described in JP 5938536 B can be used. Of such solvents, anisole, propylene glycol monomethyl ether acetate (PGMEA), cyclopentanone, cyclohexanone, or methyl 3-methoxypropionate is preferable as the solvent from a viewpoint of obtaining a positive resist composition of suitable viscosity and improving coatability of the positive resist composition.

### EXAMPLES

The following provides a more specific description of the present disclosure based on examples. However, the present disclosure is not limited to the following examples. In the following description, “%” and “parts” used in expressing quantities are by mass, unless otherwise specified.

In the examples and comparative example, the following methods were used to measure and evaluate the glass-transition temperature and sensitivity of a polymer, and the dry etching resistance of a resist pattern.

<Glass-Transition Temperature>

A differential scanning calorimeter (DSC7000 produced by Hitachi High-Tech Science Corporation) was used to measure approximately 25 mg of an obtained polymer twice at a heating rate of 10° C./min in a range of 40° C. to 240° C. while in a stream of nitrogen gas. An intersection point of the baseline of the DSC curve with a tangent at an inflection point of the DSC curve during the second measurement was taken to be the glass-transition temperature (° C.) and was evaluated by the following standard. A higher polymer glass-transition temperature indicates that an obtained resist pattern will have higher heat resistance.

A: Glass-transition temperature of higher than 150° C.

B: Glass-transition temperature of not lower than 130° C. and not higher than 150° C.

C: Glass-transition temperature of lower than 130° C.

<Sensitivity>

First, the number-average molecular weight (Mn0) of an obtained polymer was measured. Next, 0.5 g polymer samples taken from the obtained polymer were each sealed in a glass sample tube in a stream of nitrogen gas. The polymer samples were irradiated with four levels of intensity (40 kGy, 80 kGy, 120 kGy, and 160 kGy) of γ-rays (⁶⁰Co source). After γ-ray irradiation, the polymer samples were dissolved in tetrahydrofuran or dimethylformamide and the number-average molecular weight (Mn) thereof after γ-ray irradiation was measured.

The number average molecular weight (Mn) was determined as a value in terms of standard polystyrene using a gel permeation chromatograph (HLC-8220 produced by Tosoh Corporation) in which a TSKgel G4000HXL, a TSKgel G2000HXL, and a TSKgel G1000HXL (each produced by Tosoh Corporation) were linked as a column and using tetrahydrofuran or dimethylformamide as a developing solvent.

“Gs (the number of bond scissions upon absorption of 100 eV of energy)” was calculated from the measured values (Mn0 and Mn) and the following formula (1). Specifically, a graph was plotted with the “reciprocal of the number-average molecular weight of the polymer (1/Mn)” on the vertical axis and the “absorbed γ-ray dose (Gy)” on the horizontal axis, “Gs” was calculated from the gradient of the “reciprocal of the number-average molecular weight of the polymer (1/Mn)”, and sensitivity was evaluated by the following standard. A larger value for Gs indicates higher sensitivity.

A: Gs of more than 4.5

B: Gs of not less than 3.5 and not more than 4.5

C: Gs of less than 3.5

$$\frac{1}{Mn} = \frac{1}{Mn 0} + 1.04 \times {10}^{- 10} GsD \qquad ( 1 )$$

Mn: Number-average molecular weight after γ-ray irradiation

Mn0: Number-average molecular weight before γ-ray irradiation

D: Absorbed γ-ray dose (Gy)

<Dry Etching Resistance>

A positive resist composition (polymer concentration: 2.5 mass %) was obtained by dissolving a polymer in cyclopentanone and then filtering the resultant solution through a 0.25 μm polyethylene filter. A spin coater was used to apply the obtained positive resist composition onto a silicon wafer of 4 inches in diameter. Next, the applied positive resist composition was heated for 3 minutes by a hot-plate at a temperature of 180° C. to form a resist film of approximately 150 nm in thickness. The thickness T0 (nm) of the resist film was measured. Next, the silicon wafer with the attached resist film was introduced into a sputtering apparatus and was subjected to 1 minute of reverse sputtering with oxygen plasma. The thickness T1 (nm) of the resist film after the reverse sputtering was measured. The film loss rate (=T0−T1 [film loss per 1 minute; units: nm/min]) was calculated and dry etching resistance was evaluated by the following standard. A smaller value for the film loss rate indicates higher dry etching resistance.

A: Film loss rate of less than 23 nm/min

B: Film loss rate of not less than 23 nm/min and less than 26 nm/min

C: Film loss rate of 26 nm/min or more

### Example 1

<Synthesis of Monomer (a-1)>

A three-necked flask to which a Dean-Stark apparatus had been attached was charged with 56.3 g of 2,3-dichloropropionic acid, 50.0 g of 1-adamantanol, 1.9 g of dimesitylammonium pentafluorobenzenesulfonate, and 200 mL of toluene in a stream of nitrogen. Thereafter, the flask was heated and a reaction was carried out for 17 hours (12 hours at 80° C. and 5 hours at 110° C.) while evaporating produced water.

The reaction liquid was cooled to room temperature, 300 mL of hexane was subsequently added, and then the reaction liquid was further cooled to 0° C. Next, 50 g of triethylamine was slowly added dropwise, the reaction liquid was heated to room temperature, and a reaction was carried out for 5 hours. Precipitated salt was filtered off using a Kiriyama funnel and was washed twice with 50 mL of hexane. The filtrate and washings were subjected to a liquid separation operation twice using 1 M hydrochloric acid, twice using saturated sodium hydrogen carbonate aqueous solution, and twice using brine. Anhydrous magnesium sulfate was added to the organic layer and then the organic layer was filtered. The filtrate was concentrated in an evaporator. Hexane was added to the concentrate, heating was performed to 60° C. to cause dissolution, and then cooling was performed to 0° C. to cause precipitation of crystals. The crystals were filtered off using a Kiriyama funnel and were dried under reduced pressure at room temperature for 24 hours to yield a monomer (a-1) having the structure in the following formula.

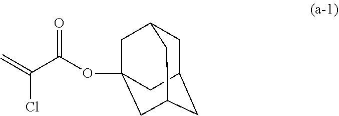 [SMILES: C=C(Cl)C(=O)OC12CC3CC(CC(C3)C1)C2]

### <Synthesis of Polymer 1>

A glass ampoule in which a stirrer had been placed was charged with 5.00 g of the monomer (a-1), 5.75 g of α-methylstyrene as a monomer (b), 0.0008 g of azobisisobutyronitrile as a polymerization initiator, and 2.69 g of cyclopentanone as a solvent and was tightly sealed. Oxygen was removed from the system through 10 repetitions of pressurization and depressurization with nitrogen gas.

The system was then heated to 78° C. and a reaction was carried out for 6 hours. Next, 10 g of tetrahydrofuran was added to the system and then the resultant solution was added dropwise to 1.5 L of methanol to cause precipitation of a polymerized product. Thereafter, the precipitated polymerized product was collected by filtration and was then dissolved in 10 g of tetrahydrofuran. The resultant solution was added dropwise to 1.5 L of methanol. Produced sediment was collected by filtration and was dried for 24 hours at 50° C. to yield a polymer 1 comprising 50 mol % each of the following two types of monomer units.

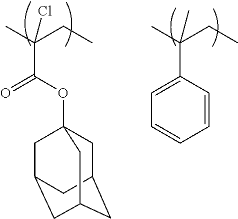

The obtained polymer 1 was used to evaluate the glass-transition temperature, sensitivity, and dry etching resistance. The results are shown in Table 1.

### Example 2

<Synthesis of Monomer (a-2)>

A three-necked flask to which a Dean-Stark apparatus had been attached was charged with 56.3 g of 2,3-dichloropropionic acid, 50.0 g of 2-adamantanol, 1.9 g of dimesitylammonium pentafluorobenzenesulfonate, and 200 mL of toluene in a stream of nitrogen. The flask was heated to 120° C. and a reaction was carried out for 24 hours while evaporating produced water.

The reaction liquid was cooled to room temperature, 300 mL of hexane was subsequently added, and then the reaction liquid was further cooled to 0° C. Next, 50 g of triethylamine was slowly added dropwise, the reaction liquid was heated to room temperature, and a reaction was carried out for 5 hours. Precipitated salt was filtered off using a Kiriyama funnel and was washed twice with 50 mL of hexane. The filtrate and washings were subjected to a liquid separation operation twice using 1 M hydrochloric acid, twice using saturated sodium hydrogen carbonate aqueous solution, and twice using brine. Anhydrous magnesium sulfate was added to the organic layer and then the organic layer was filtered. The filtrate was concentrated in an evaporator. Hexane was added to the concentrate, heating was performed to 60° C. to cause dissolution, and then cooling was performed to 0° C. to cause precipitation of crystals. The crystals were filtered off using a Kiriyama funnel and were dried under reduced pressure at room temperature for 24 hours to yield a monomer (a-2) having the structure in the following formula.

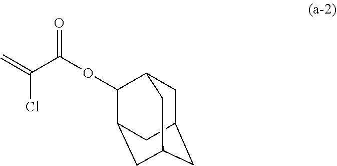 [SMILES: C=C(Cl)C(=O)OC1C2CC3CC(C2)CC1C3]

### <Synthesis of Polymer 2>

A glass ampoule in which a stirrer had been placed was charged with 5.00 g of the monomer (a-2), 5.75 g of α-methylstyrene as a monomer (b), 0.0008 g of azobisisobutyronitrile as a polymerization initiator, and 2.69 g of cyclopentanone as a solvent and was tightly sealed. Oxygen was removed from the system through 10 repetitions of pressurization and depressurization with nitrogen gas.

The system was then heated to 78° C. and a reaction was carried out for 6 hours. Next, 10 g of tetrahydrofuran was added to the system and then the resultant solution was added dropwise to 1.5 L of methanol to cause precipitation of a polymerized product. Thereafter, the precipitated polymerized product was collected by filtration and was then dissolved in 10 g of tetrahydrofuran. The resultant solution was added dropwise to 1.5 L of methanol. Produced sediment was collected by filtration and was dried for 24 hours at 50° C. to yield a polymer 2 comprising 50 mol % each of the following two types of monomer units.

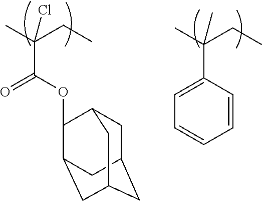

The obtained polymer 2 was used to evaluate the glass-transition temperature, sensitivity, and dry etching resistance. The results are shown in Table 1.

### Example 3

<Synthesis of Monomer (a-3)>

A three-necked flask to which a Dean-Stark apparatus had been attached was charged with 25.3 g of 2,3-dichloropropionic acid, 24.5 g of 1-adamantanemethanol, 0.7 g of dimesitylammonium pentafluorobenzenesulfonate, and 100 mL of toluene in a stream of nitrogen. The flask was heated and a reaction was carried out for 16 hours (12 hours at 80° C. and 4 hours at 130° C.) while evaporating produced water.

The reaction liquid was cooled to room temperature, 150 mL of hexane was subsequently added, and then the reaction liquid was further cooled to 0° C. Next, 22.5 g of triethylamine was slowly added dropwise, the reaction liquid was heated to room temperature, and a reaction was carried out for 5 hours. Precipitated salt was filtered off using a Kiriyama funnel and was washed twice with 25 mL of hexane. The filtrate and washings were subjected to a liquid separation operation twice using 1 M hydrochloric acid, twice using saturated sodium hydrogen carbonate aqueous solution, and twice using brine. Anhydrous magnesium sulfate was added to the organic layer and then the organic layer was filtered. The filtrate was concentrated in an evaporator. A small amount of hexane was added to the concentrate, filtration was performed using a Kiriyama funnel, and then drying under reduced pressure was performed for 24 hours at room temperature to yield a monomer (a-3) having the structure in the following formula.

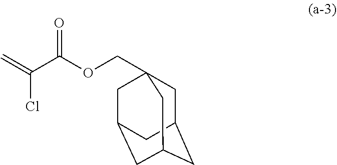 [SMILES: C=C(Cl)C(=O)OCC12CC3CC(CC(C3)C1)C2]

### <Synthesis of Polymer 3>

A glass ampoule in which a stirrer had been placed was charged with 5.00 g of the monomer (a-3), 5.43 g of α-methylstyrene as a monomer (b), 0.00075 g of azobisisobutyronitrile as a polymerization initiator, and 2.60 g of cyclopentanone as a solvent and was tightly sealed. Oxygen was removed from the system through 10 repetitions of pressurization and depressurization with nitrogen gas.

The system was then heated to 78° C. and a reaction was carried out for 6 hours. Next, 10 g of tetrahydrofuran was added to the system and then the resultant solution was added dropwise to 1.5 L of methanol to cause precipitation of a polymerized product. Thereafter, the precipitated polymerized product was collected by filtration and was then dissolved in 10 g of tetrahydrofuran. The resultant solution was added dropwise to 1.5 L of methanol. Produced sediment was collected by filtration and was dried for 24 hours at 50° C. to yield a polymer 3 comprising 50 mol % each of the following two types of monomer units.

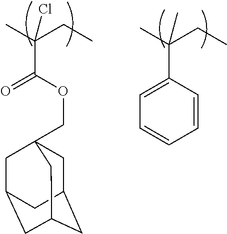

The obtained polymer 3 was used to evaluate the glass-transition temperature, sensitivity, and dry etching resistance. The results are shown in Table 1.

### Example 4

<Synthesis of Monomer (a-4)>

A three-necked flask to which a Dean-Stark apparatus had been attached was charged with 38.6 g of 2,3-dichloropropionic acid, 50.0 g of isoborneol, 1.4 g of dimesitylammonium pentafluorobenzenesulfonate, and 200 mL of toluene in a stream of nitrogen. The flask was heated and a reaction was carried out for 12 hours at from 110° C. to 130° C. while evaporating produced water.

The reaction liquid was cooled to room temperature, 300 mL of hexane was subsequently added, and then the reaction liquid was further cooled to 0° C. Next, 50 g of triethylamine was slowly added dropwise, the reaction liquid was heated to room temperature, and a reaction was carried out for 5 hours. Precipitated salt was filtered off using a Kiriyama funnel and was washed twice with 50 mL of hexane. The filtrate and washings were subjected to a liquid separation operation twice using 1 M hydrochloric acid, twice using saturated sodium hydrogen carbonate aqueous solution, and twice using brine. Anhydrous magnesium sulfate was added to the organic layer and then the organic layer was filtered. The filtrate was concentrated in an evaporator. The concentrate was vacuum distilled to yield a monomer (a-4) having the structure in the following formula.

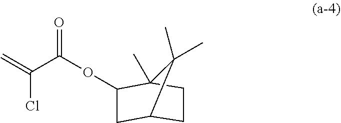 [SMILES: C=C(Cl)C(=O)OC1CC2CCC1(C)C2(C)C]

### <Synthesis of Polymer 4>

A glass ampoule in which a stirrer had been placed was charged with 5.00 g of the monomer (a-4), 5.69 g of α-methylstyrene as a monomer (b), 0.0004 g of azobisisobutyronitrile as a polymerization initiator, and 2.67 g of cyclopentanone as a solvent and was tightly sealed. Oxygen was removed from the system through 10 repetitions of pressurization and depressurization with nitrogen gas.

The system was then heated to 78° C. and a reaction was carried out for 6 hours. Next, 10 g of tetrahydrofuran was added to the system and then the resultant solution was added dropwise to 1.5 L of methanol to cause precipitation of a polymerized product. Thereafter, the precipitated polymerized product was collected by filtration and was then dissolved in 10 g of tetrahydrofuran. The resultant solution was added dropwise to 1.5 L of methanol. Produced sediment was collected by filtration and was dried for 24 hours at 50° C. to yield a polymer 4 comprising 50 mol % each of the following two types of monomer units.

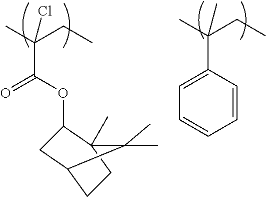

The obtained polymer 4 was used to evaluate the glass-transition temperature, sensitivity, and dry etching resistance. The results are shown in Table 1.

### Example 5

<Synthesis of Monomer (a-5)>

A three-necked flask to which a Dean-Stark apparatus had been attached was charged with 27.8 g of 2,3-dichloropropionic acid, 25.0 g of hydroxynorbornalactone, 1.0 g of dimesitylammonium pentafluorobenzenesulfonate, and 150 mL of toluene in a stream of nitrogen. The flask was heated to 130° C. and a reaction was carried out for 24 hours while evaporating produced water.

The reaction liquid was cooled to room temperature, 150 mL of diethyl ether was subsequently added, and then the reaction liquid was further cooled to 0° C. Next, 24.6 g of triethylamine was slowly added dropwise, the reaction liquid was heated to room temperature, and a reaction was carried out for 5 hours. Precipitated salt was filtered off using a Kiriyama funnel and was washed twice with 25 mL of diethyl ether. The filtrate and washings were subjected to a liquid separation operation twice using 1 M hydrochloric acid, twice using saturated sodium hydrogen carbonate aqueous solution, and twice using brine. Anhydrous magnesium sulfate was added to the organic layer and then the organic layer was filtered. The filtrate was concentrated in an evaporator. The concentrate was dissolved in a small amount of tetrahydrofuran and was then added into a large amount of hexane to obtain a precipitate. The precipitate was collected by filtration and was dried under reduced pressure at room temperature for 24 hours to yield a monomer (a-5) having the structure in the following formula.

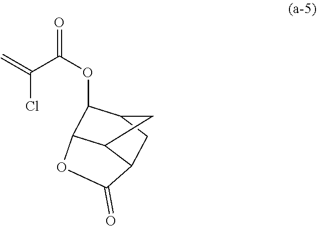 [SMILES: C=C(Cl)C(=O)OC1C2CC3C(=O)OC1C3C2]

### <Synthesis of Polymer 5>

A glass ampoule in which a stirrer had been placed was charged with 5.00 g of the monomer (a-5), 5.70 g of α-methylstyrene as a monomer (b), 0.0008 g of azobisisobutyronitrile as a polymerization initiator, and 2.67 g of cyclopentanone as a solvent and was tightly sealed. Oxygen was removed from the system through 10 repetitions of pressurization and depressurization with nitrogen gas.

The system was then heated to 78° C. and a reaction was carried out for 6 hours. Next, 10 g of tetrahydrofuran was added to the system and then the resultant solution was added dropwise to 1.5 L of methanol to cause precipitation of a polymerized product. Thereafter, the precipitated polymerized product was collected by filtration and was then dissolved in 10 g of tetrahydrofuran. The resultant solution was added dropwise to 1.5 L of methanol. Produced sediment was collected by filtration and was dried for 24 hours at 50° C. to yield a polymer 5 comprising 50 mol % each of the following two types of monomer units.

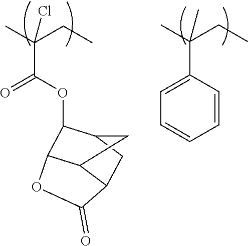

The obtained polymer 5 was used to evaluate the glass-transition temperature, sensitivity, and dry etching resistance. The results are shown in Table 1.

### Comparative Example 1

### <Synthesis of Polymer 6>

A glass vessel was charged with a monomer composition containing 3.0 g of methyl α-chloroacrylate and 6.88 g of α-methylstyrene as monomers, 2.47 g of cyclopentanone as a solvent, and 0.01091 g of azobisisobutyronitrile as a polymerization initiator. The glass vessel was tightly sealed and was purged with nitrogen. The glass vessel was then stirred for 6.5 hours under a nitrogen atmosphere in a 78° C. thermostatic tank. Thereafter, the glass vessel was returned to room temperature, the inside of the glass vessel was exposed to the atmosphere, and 30 g of tetrahydrofuran was added to the resultant solution. The solution to which tetrahydrofuran had been added was added dropwise to 300 g of methanol to cause precipitation of a polymerized product. Thereafter, the solution containing the polymerized product that had precipitated was filtered using a Kiriyama funnel to obtain a white coagulated material (polymer 6). The obtained polymer 6 comprised 50 mol % each of α-methylstyrene units and methyl α-chloroacrylate units.

The obtained polymer 6 was used to evaluate the glass-transition temperature, sensitivity, and dry etching resistance. The results are shown in Table 1.

TABLE 1

| | | | | | | Comparative |
|---|---|---|---|---|---|---|
| | Example 1 | Example 2 | Example 3 | Example 4 | Example 5 | Example 1 |
| Type of | Polymer 1 | Polymer 2 | Polymer 3 | Polymer 4 | Polymer 5 | Polymer 6 |
| polymer | | | | | | |
| Glass- | A | A | B | A | A | B |
| transition | | | | | | |
| temperature | | | | | | |
| Sensitivity | A | A | B | B | B | B |
| Dry etching | A | A | A | B | A | C |
| resistance | | | | | | |

It can be seen from Table 1 that the polymers of Examples 1 to 5, which each include the monomer unit (A) and the monomer unit (B), can improve dry etching resistance of a resist pattern compared to the polymer of Comparative Example 1, which does not include the monomer unit (A).

### INDUSTRIAL APPLICABILITY

According to the present disclosure, it is possible to provide a polymer that can form a resist pattern having excellent dry etching resistance when used as a main chain scission-type positive resist.

Moreover, according to the present disclosure, it is possible to provide a positive resist composition that can form a resist pattern having excellent dry etching resistance.

1. A polymer comprising:
a monomer unit (A) represented by formula (I), shown below, 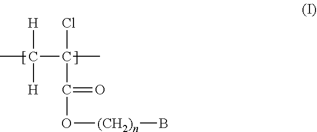
where, in formula (I), B is a bridged saturated hydrocarbon cyclic group that is optionally substituted and n is 0 or 1; and
a monomer unit (B) represented by formula (II), shown below, 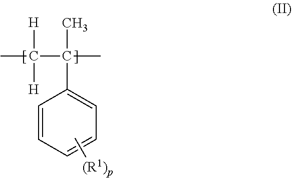
where, in formula (II), R¹ is an alkyl group and p is an integer of not less than 0 and not more than 5, and in a case in which more than one 10 is present, each 10 may be the same or different.

2. The polymer according to claim 1, wherein n is 0.

3. The polymer according to claim 1, wherein B is an optionally substituted adamantyl group.

4. A positive resist composition comprising: the polymer according to claim 1; and a solvent.
